(19) United States
(12) Patent Application Publication
(10) Pub. No.: US 2024/0310558 A1
(43) Pub. Date: Sep. 19, 2024

(54) ZEIN-BASED PHOTONIC CRYSTALS AND USES THEREOF

(71) Applicant: Northeastern University, Boston, MA (US)

(72) Inventors: Leila Deravi, Cambridge, MA (US); Patrick Sullivan, Cambridge, MA (US); Zhuangsheng Lin, Dedham, MA (US); Cassandra Leigh Martin, Boston, MA (US); Ivy Wang, Diamond Bar, CA (US); Duncan Bower, Winchester, MA (US)

(21) Appl. No.: 18/577,919

(22) PCT Filed: Jul. 8, 2022
(86) PCT No.: PCT/US2022/073530

§ 371 Date: Jan. 9, 2024

Related U.S. Application Data
(60) Provisional application No. 63/220,462, filed on Jul. 10, 2021.

(51) Int. Cl. G02B 1/00; B82Y 20/00; C09B 19/00; C09B 67/48; G02B 1/118

(52) U.S. Cl. CPC G02B 1/005; B82Y 20/00; C09B 19/00; C09B 67/0025; G02B 1/118; G02B 2207/101

(57) ABSTRACT

Described herein are photonic crystals comprising a plurality of substantially uniform zein particles. The photonic crystals can be fabricated by assembling the plurality of substantially uniform zein particles into one or more ordered and periodic structures that generate structural color. Also described herein are methods of using the photonic crystals described herein, e.g., as colorants in consumer products, such as food, drugs and/or cosmetics.

### RELATED APPLICATION

This application claims the benefit of U.S. Provisional Application No. 63/220,462, filed on Jul. 10, 2021. The entire teachings of this application are incorporated herein by reference.

### BACKGROUND

Coloring systems are widely used in food and consumer products as colorants and sometimes as colorimetric sensors to indicate product quality. The coloring systems used in these products (e.g., food, drugs, cosmetics), and associated packages and contact surfaces, are usually pigment based. Pigment-based colors rely on electronic excitation to generate color. The color properties of pigment-based color are inherent of the material and depend on the chemical nature of the pigment. Pigment-based color, especially pigment-based color derived from naturally-derived pigments, has limitations, such as lack of stability, and pigments do not exist for all hues. More importantly, there is concern over unfavorable influences on health and the environment, as some artificial colorants contain harmful substances.

Unlike pigment-based color, photonic crystals contain periodically ordered nano- or microstructures and can generate structural color from reflection, diffuse reflection, diffraction, and interference of light. Because electronic excitation is not required for coloration, structural color is not susceptible to fading unless the nano- and micro-structure is destroyed.

Photonic crystals are commonly prepared using synthetic polymers, such as polystyrene and silica materials, and are not edible and not safe for food, cosmetic and drug applications.

Accordingly, there is a need for coloring systems that overcome the deficiencies of pigment-based color.

### SUMMARY

Described herein are photonic crystals comprising a plurality of substantially uniform zein particles. Zein is classified as Generally Regarded As Safe (GRAS) and can be used, for example, as colorants in food, drug, cosmetic and other consumer coatings and applications.

Accordingly, also described herein are colorants, compositions and/or sensors comprising a photonic crystal described herein.

Also described herein are methods of fabricating a photonic crystal comprising assembling a plurality of substantially uniform zein particles into one or more ordered and periodic structures that generate structural color, thereby fabricating the photonic crystal.

Also described herein are methods of imparting a color to a surface, comprising coating a surface, or a portion thereof, with a photonic crystal described herein.

The photonic crystals described herein were prepared from naturally-derived compounds (e.g., zein, which is derived from corn, an edible plant) using green chemistry. The photonic crystals described herein can be used to generate structural colors that are chemically more stable and more vivid than pigment-based counterparts, especially naturally-derived pigments. By controlling the size and packing density of the particles in the photonic crystal, and the thickness of the assembled photonic crystals, the natural light reflecting and scattering properties of these materials can be leveraged to generate structural colors that span the entire visible light spectrum. The resultant photonic crystals are edible, are safe to be used in food, cosmetic and drug products, as well as the packages and contact surfaces of such products, and may offer additional benefits (e.g., health benefits) other than their optical features.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings.

FIG. 1 shows a design of a naturally-derived photonic crystal color system using zein nanoparticles patterned into films and coating materials producing visible colors that span the entire visible spectrum. The photonic crystal color system can be used as an alternative color system for food and consumer products.

FIG. 2 is a schematic showing the protocol for the generation of zein nanoparticles.

FIG. 3 shows predicted reflected wavelengths as a function of ϕ versus a at np=1.49. The refractive index (RI) of the surrounding matrix is 1.33 (the RI of water). Only the wavelengths located in the visible region are shown, and the wavelengths are formatted based on their corresponding color, using https://academo.org/demos/wavelength-to-colour-relationship/to convert wavelength to a red, green, and blue (RGB) value.

FIG. 4 shows that embodiments of the disclosure can be used as structural color sensors for food packages and food contact surfaces. Sensors are assembled by the formation of nanoparticles into thin films producing visible colors that span the visible spectrum, such as the blue shown in FIG. 4. The photonic crystal sensors can undergo color change upon contact with volatile organic compounds produced by food spoilage. Incorporating such sensor into food packaging enables in situ monitoring of food quality and safety.

FIG. 5A shows picture of photonic crystal sensors exposed to different headspace vapor.

FIG. 5B is a representative scanning electron microscopy (SEM) micrograph of highly ordered nanostructure of photonic crystals.

FIG. 5C is a diffuse reflectance spectrum of the photonic crystals depicted in FIG. 5A, measured at an 8º tilt angle.

FIG. 6 shows a concept of an edible colorimetric sensor in foods: photonic crystal supraball prepared using zein nanoparticles with a chitosan coating. The coating can be hydrolyzed by enzymes (e.g., amylase) released by food spoilage microorganisms, and the destruction of the supraball nanostructure leads to loss of structural color.

FIG. 7A is an image of WHATMAN™ filter paper glued with zein adhesive, and shows adhesive quality of zein as a glue for WHATMAN™ filter paper.

FIG. 7B is an image of the glued paper in FIG. 7A when mechanically stretched.

FIG. 7C is an image showing the point of failure of the glued paper in FIGS. 7A and 7B when mechanically stretched.

FIG. 7D is an image of the glued paper in FIG. 7A showing that weight can be suspended from the glued paper.

FIG. 8 is an image of a paper-based construct held together with zein.

FIG. 9A are images of a pellet of zein nanoparticles after centrifugation at 5,000 relative centrifugal force (rcf) for 5 minutes (image on the left), and a pellet of zein nanoparticles encapsulating xanthommatin after centrifugation at 5,000 rcf for 5 minutes (image on the right).

FIG. 9B is an absorption spectrum revealing that the supernatant of the nanoparticles formed in FIG. 9A was missing the characteristic 450 nm peak that is indicative of xanthommatin.

FIG. 9C is an absorption spectrum presenting the characteristic peak at 450 nm for xanthommatin being present in zein nanoparticles formed in the presence of xanthommatin even after washing of the nanoparticles.

FIG. 10A is a representative scanning electron microscopy (SEM) micrograph of a suspension of zein nanoparticles having diameters of approximately 150 nm from Example 9 diluted 1:1 in 65% volume/volume (v/v) ethanol in water (scale bar=1 μm).

FIG. 10B is a representative scanning electron microscopy (SEM) micrograph of a suspension of zein nanoparticles having diameters of approximately 150 nm from Example 9 diluted 1:4 in 65% v/v ethanol in water (scale bar=1 μm).

FIG. 11A shows images of yellow suspensions of zein nanoparticles from Example 9 undiluted or diluted 1:1, 1:2, 1:4 or 1:9 in 65% v/v ethanol in water and drop-casted into blue iridescent films.

FIG. 11B is a graph, and shows transmittance of the casted films in FIG. 11A over the indicated range of wavelengths.

FIG. 12A shows SEM images of indicated dilutions of nanoparticles from Example 10 dropped onto glass using a 10 μl drop size.

FIG. 12B shows bright field images of films casted from indicated dilutions of zein nanoparticles from Example 10 dropped onto glass.

FIG. 12C shows reflectance of films casted from indicated dilutions of nanoparticles from the no salt conditions from Example 10.

FIG. 12D shows reflectance of films casted from indicated dilutions of nanoparticles from the 7 mM CaCl₂) conditions from Example 10.

FIG. 12E shows reflectance of films casted from indicated dilutions of nanoparticles from the 7 mM NaCl conditions from Example 10.

FIG. 12F shows reflectance of films casted from undiluted nanoparticles from the 3.5 mM CaCl₂ ultrapure conditions from Example 10.

### DETAILED DESCRIPTION

A description of example embodiments follows.

### Photonic Crystals and Colorants, Compositions And Sensors Incorporating Same

Photonic crystals prepared from synthetic polymers have a wide array of applications, such as full color displays, photonic pigments, and colorimetric sensing. According to an example embodiment of this invention, photonic crystals are prepared using a Generally Regarded As Safe (GRAS) naturally-derived protein known as zein using green chemistry. The resultant photonic crystals are believed to be safe to be used in food and consumer products, as well as in the packages and contact surfaces of food and consumer products. The use of the naturally-derived photonic crystals serves as a promising alternative to the current pigment-based color systems in food and consumer products.

Described herein are photonic crystals comprising a plurality of substantially uniform zein particles (e.g., zein nanoparticles). In some aspects, the photonic crystal is in the form of a film. In some aspects, the photonic crystal is in the form of a thin film. In some aspects, the photonic crystal is in the form of a coating. In some aspects, the photonic crystal is in the form of a supraball.

As used herein, singular articles such as “a,” “an” and “the,” and similar referents are to be construed to cover both the singular and the plural, unless otherwise indicated herein or clearly contradicted by context. For example, reference to “a pigment” may refer to one or more pigments. When a referent refers to the plural, the members of the plural can be the same as or different from one another.

As used herein, “photonic crystal” refers to a one-, two-, or three-dimensional array of particles with an ordered and periodic structure that generates structural color. Typically, structural color in a photonic crystal is due to periodic changes in the refractive index of the array of particles. In some aspects, a photonic crystal is one-dimensional, as, for example, when the photonic crystal is in the form of a film or thin film. In some aspects, a photonic crystal is two-dimensional, as, for example, when the photonic crystal is in the form of a substrate comprising holes generated by photolithography. In some aspects, a photonic crystal is three-dimensional, as, for example, when the photonic crystal is in the form of multiple two-dimensional layers on top of each other, or in the form of particles assembled in a three-dimensional shape, for example, a supraball. Photonic crystals can be fabricated using methods described herein and/or known in the art.

As used herein, “thin film” refers to a layer or coating of material that is less than about 10 micrometers in thickness.

It is understood from Equation 1 (in Example 1) that photonic crystal-based color systems produce coloration largely based on diffraction which occurs when light reaches an object or slit on the same size order of the wavelength of light and bends around it. It is also understood from Equation 2 (in Example 1) that the wavelength of reflected structural color in photonic crystal-based color systems can be predicted using Bragg's equation.

The visible color spectrum is typically considered to extend from about 380 nanometers to about 780 nanometers. Thus, for example, a red color can be derived from light with a wavelength of about 620 to about 780 nanometers. An orange color can be derived from light with a wavelength of about 590 to about 620 nanometers. A yellow color can be derived from light with a wavelength of about 570 to about 590 nanometers. A green color can be derived from light with a wavelength of about 495 to about 570 nanometers. A blue color can be derived from light with a wavelength of about 435 to about 495 nanometers. A purple color can be derived from light with a wavelength of about 380 to about 435 nanometers.

Zein is a corn alcohol soluble storage protein that can form hydrophobic, water-insoluble biopolymers due to its high percentage of non-polar amino acids. Zein is an attractive biopolymer for research due to its abundance, biodegradability, sustainability, and its approval for oral use by U.S. Food and Drug Administration (FDA). Zein and its precursors and derivatives can be obtained from natural resources such as corn. They can also be synthesized using methods described herein and/or known in the art.

As used herein, “substantially uniform” refers to particles that, when arrayed in an ordered and periodic structure, are capable of generating structural color. Because zein-based nanoparticles have a refractive index of 1.49, it is expected that the size and spacing of the particles will be the primary factors for controlling reflected wavelength, allowing more freedom in the morphology of the particles. Thus, in some aspects, “substantially uniform” is conveniently described herein in terms of particle diameter (e.g., mean particle diameter) and/or particle size distribution (e.g., polydispersity index (PDI), d₉₀).

Particle size analysis can be used to measure particle size and, often, the size distribution of particles in a sample. Most particle sizing techniques measure a one-dimensional property of a particle (e.g., diameter), and relate the measured property to the size of an equivalent sphere. Particle size can be expressed as a mean of a representative sample, such as a representative number of zein nanoparticles. Methods of measuring particle size (e.g., particle diameter) are known in the art, and include direct imaging (e.g., using a cell counter), laser diffraction, dynamic light scattering (DLS) and scanning electron microscopy (SEM).

In some aspects, the plurality of substantially uniform zein particles have a diameter (e.g., mean diameter, or mean core diameter) of about 50 nanometers to about 300 nanometers, e.g., about 50 nanometers to about 250 nanometers, about 50 nanometers to about 200 nanometers, about 50 nanometers to about 150 nanometers, about 100 nanometers to about 200 nanometers or about 150 nanometers to about 300 nanometers. In some aspects, the plurality of substantially uniform zein particles have a diameter (e.g., mean diameter, mean core diameter) of about 145 nanometers to about 200 nanometers. In some aspects, the plurality of substantially uniform zein particles have a diameter (e.g., mean diameter, mean core diameter) of about 200 nanometers.

“About” means within an acceptable error range for the particular value, as determined by one of ordinary skill in the art. Typically, an acceptable error range for a particular value depends, at least in part, on how the value is measured or determined, e.g., the limitations of the measurement system. For example, “about” can mean within an acceptable standard deviation, per the practice in the art. Alternatively, “about” can mean a range of ±20%, e.g., ±10%, ±5% or ±1% of a given value. It is to be understood that the term “about” can precede any particular value specified herein, except for particular values used in the Exemplification.

Particle size distribution is a means of expressing what sizes of particles in what proportions are present in a population of particles. Methods of measuring particle size distribution (e.g., polydispersity index, don) are known in the art, and include laser diffraction.

In some aspects, a plurality of zein nanoparticles have a particle size distribution of ±5 standard deviations from the mean particle size (e.g., as expressed by mean particle diameter), e.g., ±4 standard deviations from the mean particle size, ±3 standard deviations from the mean particle size, ±2 standard deviations from the mean particle size, ±1 standard deviation from the mean particle size, ±0.5 standard deviations from the mean particle size, or +0.1 standard deviations from the mean particle size.

In some aspects, a plurality of zein nanoparticles have a PDI (e.g., average PDI) of 0.5 or less, e.g., 0.4 or less, 0.3 or less, 0.25 or less, 0.2 or less, 0.18 or less, 0.16 or less, 0.15 or less, 0.14 or less, 0.13 or less, 0.12 or less, or 0.1 or less. In some aspects, a plurality of zein nanoparticles have a PDI of about 0.2 or less, e.g., about 0.18, or about 0.16, or about 0.15, or about 0.1, or about 0.05 to about 0.2, or about 0.1 to about 0.2.

Volume fraction is a description of the volume of a constituent divided by the volume of all constituents in a mixture prior to mixing. In some aspects, the particle volume fraction is the volume of the particles divided by the volume of the particles and the volume of the liquid mixture that is suspending the particles. Volume fraction is a dimensionless value and is expressed as a number between 0 and 1. Methods of measuring volume fraction (e.g., 0.75) are known in the art, and include confocal microscopy and particle counting.

In some aspects, the plurality of substantially uniform zein particles have a volume fraction (φ) of about 0.02 to about 0.95, e.g., about 0.05 to about 0.9, about 0.1 to about 0.9, about 0.25 to about 0.9, about 0.5 to about 0.9, about 0.5 to about 0.85, about 0.6 to about 0.8 or about 0.7 to about 0.8. In some aspects, the plurality of substantially uniform zein particles have a volume fraction (φ) of about 0.04 to about 0.75. In some aspects, the plurality of substantially uniform zein particles have a volume fraction (φ) of about 0.70 to about 0.95.

In some aspects, the plurality of substantially uniform zein particles have a zeta potential (e.g., mean zeta potential) of about 10 mV to about 100 mV, e.g., about 20 mV to about 75 mV, or about 20 mV to about 50 mV. In some aspects, the plurality of substantially uniform zein particles have a zeta potential of about 20 mV to about 60 mV. Without wishing to be bound by any particular theory, it is believed that particles with a higher surface charge are less likely to aggregate in suspension and/or solution.

Particle packing density can also be used to characterize the photonic crystals described herein, in particular, photonic crystals provided in the form of a coating and/or film (e.g., thin film). Particle packing density is the ratio of the volume of the plurality of substantially uniform zein particles to the volume of the photonic crystal, and is expressed herein as a percentage. The particle packing density can be characterized by observing the number of substantially uniform zein particles that exist within an area of interest in a photonic crystal comprising a plurality of substantially uniform zein particles using one or more SEM images. By combining the observation described above with the following assumptions, particle packing density of a volume can be calculated: (1) the substantially uniform zein particles are understood to be spherical, which allows for extrapolation from transverse area to volume of the substantially uniform zein particle sphere, and (2) the surface of the photonic crystal is understood to be representative of the packing of the rest of the photonic crystal (e.g., inner layers).

In some aspects, the plurality of substantially uniform zein particles have a particle packing density (e.g. mean particle packing density) that is about 1% of the photonic crystal volume to about 100% of the photonic crystal volume, e.g., about 3% of the photonic crystal volume to about 95% of the photonic crystal volume, or about 50% of the photonic crystal volume to about 95% of the photonic crystal volume, or about 60% of the photonic crystal volume to about 95% of the photonic crystal volume, or about 75% of the photonic crystal volume to about 95% of the photonic crystal volume. In some aspects, the plurality of substantially uniform zein particles have a particle packing density that is about 90% of the photonic crystal volume.

Described herein are photonic crystals that impart a color. In some aspects, the photonic crystal imparts a blue color. In some aspects, the photonic crystal imparts a red color. In some aspects, the photonic crystal imparts an orange color. In some aspects, the photonic crystal imparts a yellow color. In some aspects, the photonic crystal imparts a green color. In some aspects, the photonic crystal imparts a purple color.

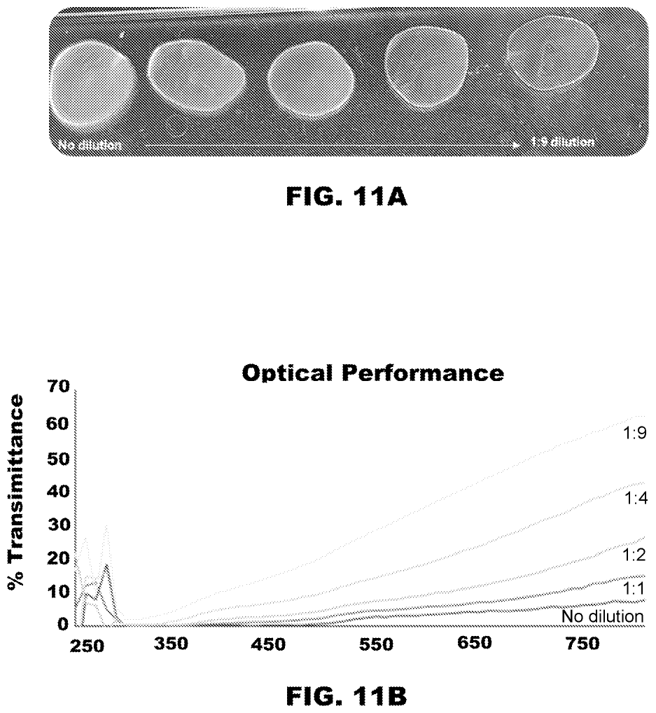

For example, and as depicted in FIG. 11A, a blue color can be imparted by a photonic crystal comprising a plurality of substantially uniform zein particles having a diameter of about 150 nanometers and a volume fraction of about 0.75. In some aspects, a photonic crystal imparts a blue color and/or comprises a plurality of substantially uniform zein particles having a diameter of about 60 nanometers to about 100 nanometers, and a volume fraction of about 0.14 to about 0.74. In some aspects, a photonic crystal imparts a red color and/or comprises a plurality of substantially uniform zein particles having a diameter of about 60 nanometers to about 150 nanometers, and a volume fraction of about 0.04 to about 0.74. In some aspects, a photonic crystal imparts an orange color and/or comprises a plurality of substantially uniform zein particles having a diameter of about 80 nanometers to about 130 nanometers, and a volume fraction of about 0.14 to about 0.74. In some aspects, a photonic crystal imparts a yellow color and/or comprises a plurality of substantially uniform zein particles having a diameter of about 50 nanometers to about 120 nanometers, and a volume fraction of about 0.04 to about 0.74. In some aspects, a photonic crystal imparts a green color and/or comprises a plurality of substantially uniform zein particles having a diameter of about 70 nanometers to about 110 nanometers, and a volume fraction of about 0.14 to about 0.74. In some aspects, a photonic crystal imparts a purple color and/or comprises a plurality of substantially uniform zein particles having a diameter of about 50 nanometers to about 90 nanometers, and a volume fraction of about 0.14 to about 0.74.

In some aspects, the zein particles comprise a colorant (e.g., pigment). In some aspects, the colorant is encapsulated in the zein particles.

Colorants can be used alone or in a mixture to impart color(s) to a photonic crystal and/or composition, such as a photonic crystal and/or composition described herein. Colorants include metal oxides and other particulate pigments, and also soluble absorbers, such as dyes. In some aspects, a colorant comprises a purple colorant, blue colorant, green colorant, yellow colorant, red colorant, black colorant, or white colorant. In some aspects, a colorant is selected from a purple colorant, blue colorant, green colorant, yellow colorant, red colorant, black colorant, or white colorant. Examples of soluble dye colorants include erioglaucine (acid blue 9) and disodium 6-hydroxy-5-[(2-methoxy-5-methyl-4-sulfophenyl)azo]-2-naphthalenesulfonate (Allura Red/Red 40). Examples of pigment colorants include titanium dioxide, red iron oxide, yellow iron oxide, carbon black, and Prussian Blue.

Common colorants are widely available, and include, but are not limited to, colorants colored purple (e.g., ultramarine violet (Al); han purple (Cu); cobalt violet; purple of cassius (Au), etc.), blue (e.g., cobalt blue; Egyptian blue (Cu); Prussian blue (Fe); etc.), green (e.g., cadmium green; chrome green (Cr); Scheele's green (Cu); etc.), yellow (e.g., orpiment (As); primrose yellow (Bi); naples yellow (Pb); etc.), orange (e.g., bismuth vanadate orange; cadmium pigments; etc.), red (e.g., red ochre (Fe); cinnabar (Hg); burnt sienna (Fe); carmine (Al); etc.), and white (e.g., antimony white; lithopone (Ba); cremnitz white (Pb); etc.).

In some aspects, a colorant is xanthommatin. As used herein, “xanthommatin” refers to 11-(3-amino-3-carboxypropanoyl)-1,5-dioxo-4H-pyrido[3,2-a]phenoxazine-3-carboxylic acid. Xanthommatin and various of its precursors and derivatives can be extracted from cephalopods (e.g., squid Doryteuthis pealeii chromatophores) and other natural sources, such as the eyes, integumentary system, organs, and eggs of arthropods. Xanthommatin and its precursors and derivatives can also be synthesized using methods described herein and/or known in the art.

In some aspects, a photonic crystal described herein is coated or encapsulated. It will be appreciated that should it be desirable for the color imparted by the photonic crystal to be visible, the material coating and/or encapsulating the photonic crystal should be transmissive (e.g., transparent). Such materials are known in the art and include, for example, a chitosan coating.

By tuning the size, packing density, and/or distribution of zein nanoparticles, highly pure structural colors can be created that can be engineered as photonic crystals with colors that span the entire visible spectrum. The photonic crystal color system also shows unique solvatochromic properties (change color in response to organic vapor) and can serve as sensors to detect volatile organic compounds released during product spoilages. Additionally, the use of zein nanoparticles to increase the stability of small molecules has been investigated to retain the characteristics of the molecules increasing their functionality and ease of application. Finally, the use of zein as an adhesive in paper-based materials has been explored to create an eco-friendly material that can be used to limit the use of polymer-based adhesives in disposable items.

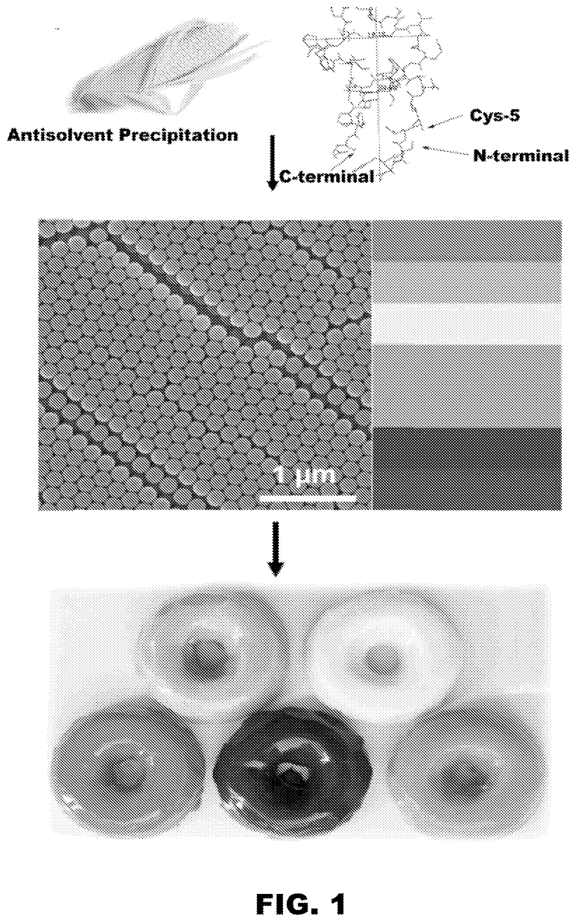

An example embodiment of the invention describes the design of naturally-derived photonic crystals comprised of assembled zein nanoparticles as a new coloring system for foods (concept illustrated in FIG. 1). By controlling the size of the particles, their packing density, and the thickness of the patterned films, the natural light reflecting and scattering properties of these materials can be leveraged. This photonic crystal color system can be used as an alternative color system for food and consumer products.

The compositions described herein have the following example uses:
Colorant, e.g., for food, drug and cosmetic products;
Intelligent packaging sensor, e.g., for food, drug and cosmetic products;
Edible colorimetric sensor, e.g., for food, drug and cosmetic products;
Adhesive, e.g., for paper-based materials; and/or
Stabilizer for pigments, such as biological pigments.

Thus, also described herein is a colorant comprising a photonic crystal described herein.

Also described herein is a composition comprising a photonic crystal described herein. In some aspects, the composition is formulated for oral use as, for example, food. In some aspects, the composition is edible. In some aspects, the composition is formulated for topical use as, for example, a cosmetic. In some aspects, the composition is for use as a consumer product. In some aspects, the composition is for use as a food, drug or cosmetic.

Also described herein is a sensor, comprising a photonic crystal described herein.

Also described herein is a stabilizer for a pigment, such as a biological pigment, such as xanthommatin. The stabilizer comprises a photonic crystal described herein, such as a photonic crystal wherein the zein nanoparticles comprise (e.g., encapsulate) the pigment (e.g., xanthommatin).

### Methods

Described herein are methods of fabricating the photonic crystals described herein. In an aspect, the method comprises assembling a plurality of substantially uniform zein particles into one or more ordered and periodic structures that generate structural color, thereby fabricating the photonic crystal. In some aspects, the method of fabricating the photonic crystal comprises:
(i) providing a mixture comprising a plurality of substantially uniform zein particles in a liquid;
(ii) applying the mixture to a surface; and
(iii) evaporating the liquid, thereby assembling the plurality of substantially uniform zein particles into one or more ordered and periodic structures that generate structural color,
   thereby fabricating a photonic crystal.

Also described herein are methods of imparting color to a surface, comprising coating a surface, or a portion thereof, with a photonic crystal. In some aspects, the method of imparting color to a surface comprises:
(i) providing a mixture comprising a plurality of substantially uniform zein particles in a liquid; and
(ii) applying the mixture to a surface, and
(iii) evaporating the liquid to produce one or more photonic crystals comprising the substantially uniform zein particles,
   thereby imparting a color to the surface.

It will be appreciated that in at least some aspects of the foregoing methods, the photonic crystal self-assembles during and/or as a result of the evaporation process. Drop-casting and vertical deposition can each be used to effect self-assembly according to the methods described herein.

In some aspects of the foregoing methods, the liquid comprises (e.g., is) a non-solvent, such as water (e.g., deionized water).

In some aspects of the foregoing methods, the method further comprises fabricating the plurality of substantially uniform zein particles, for example, using any method described herein for such purpose, or aspect thereof.

Also provided herein is a method of fabricating a plurality of substantially uniform zein nanoparticles, e.g., for use in fabrication of a photonic crystal described herein. The method comprises dissolving zein in a solvent system; and precipitating zein nanoparticles from the solvent system using a non-solvent. In some aspects, the method further comprises purifying the zein nanoparticles, for example, by centrifuging the zein nanoparticles and separating a first portion (e.g., a top layer) of the centrifuged zein nanoparticles from a second portion (e.g., a bottom layer) of the centrifuged zein nanoparticles. Purification can be used, for example, to increase particle uniformity and/or to select for desired particle properties, such as increased zeta potential and/or decreased particle size.

In some aspects, the solvent system comprises an organic solvent. In further aspects, the solvent system comprises an organic solvent and water.

Examples of organic solvents include: alkyl solvents (such as hexanes, cyclohexane, pentanes, and the like), aromatic solvents (such as benzene, toluene, and the like), alcohols (such as methanol, acidic methanol, ethanol, and the like), esters, ethers, and ketones (such as diethyl ether, acetone, and the like), amines (such as dimethyl amine and the like), and nitrated and halogenated hydrocarbons (such as dichloromethane, acetonitrile, and the like). Examples of solvent systems include acetone, ethanol, ethylene glycol or methanol and water.

In some aspects, the non-solvent comprises water.

In further aspects, the non-solvent comprises water and a salt, such as sodium chloride or calcium chloride. For instance, it has been found that 7 mM sodium chloride in water enhances particle uniformity for particles of about 200 nanometers in diameter, and that changing the salt can be used to vary diameter of the particles.

Examples of suitable salts include salts derived from an inorganic base, such as alkali metal, alkaline earth metal, and ammonium bases, and an inorganic acid, such as hydrochloric acid, hydrobromic acid, phosphoric acid, sulfuric acid and perchloric acid. Representative alkali or alkaline earth metal salts include sodium, lithium, potassium, calcium, magnesium, barium and the like.

Dilution of the nanoparticle-containing mixture being casted (e.g., dropped) has also been found to affect volume fraction of the resulting films and, hence, color of the resulting films. Thus, in some aspects, a method further comprises adjusting concentration of the zein nanoparticles (e.g., the mixture of zein nanoparticles; zein nanoparticles resulting from precipitation and/or purification of the zein nanoparticles according to a method of fabricating a plurality of substantially uniform zein nanoparticles described herein) as, for example, by centrifugation and/or dilution. Representative concentrations of a nanoparticle-containing mixture suitable for applying to a surface (e.g., as by casting or dropping) range from 0.001% mass/volume (m/v) to 100% m/v, e.g., about 0.01% mass/volume to about 50% m/v, or about 0.025% m/v to about 5% m/v, or about 0.03% m/v to about 1% m/v, or about 0.0375% m/v, or about 0.075% m/v, or about 0.375% m/v, or about 0.75% m/v.

### Exemplification

Artificial colorants are largely used in food, drug, and cosmetic products, and has raised safety concerns. It has been a billion-dollar question to the scientists and engineers in the food and cosmetic industry to replace certified artificial colorants with more label friendly natural colorants in product formulations. The photonic crystal color system described herein is prepared using naturally derived healthy compounds and is prepared using a green chemistry. Embodiments of the invention can serve as a safe and healthy alternative to artificial colorants.

Described herein is the design of naturally-derived photonic crystals comprised of assembled zein nanoparticles as a new coloring system for foods (e.g., as illustrated in FIG. 1). To prepare the photonic crystals, a solution of zein was converted into nanoparticles with diameters ranging from 50-300 nm via antisolvent precipitation. Then, the nanoparticles were processed into thin film photonic crystals to produce structural colors that covered the entire visible light spectrum. By controlling the size of the particles, their packing density, and the thickness of the patterned films, the natural light reflecting and scattering properties of these materials can be leveraged. This photonic crystal color system can be used as an alternative color system for food and consumer products.

### Example 1. Photonic Crystals

Photonic crystal-based color systems offer a unique alternative to pigment-based color systems. These crystal-like materials produce coloration largely based on diffraction which occurs when light reaches an object or slit on the same size order of the wavelength of light and bends around it. At this point, a diffraction pattern is formed, which is when certain wavelengths of light will interfere to produce patterned areas of alternating light and dark spots, usually in the same shape as the aperture or object. To increase the brilliance of the effect, the micro- or nano-structures must have a high level of periodicity, meaning they need to have consistent size and spacing, or it will result in a more diffuse reflection. Diffraction can be described using the conditions in Equation 1:

$$m λ = d ( sin {θ}_{D} - sin {θ}_{I} ) \qquad ( 1 )$$

where m is the diffraction order, Δ is the wavelength of light, d is the periodicity of the grating or structures, θ_{D} is the angle of diffracted light, and θ₁ is the angle of incident light. Biological photonic crystals are abundant in nature and are often observed as highly ordered nanostructure arrays that can generate structural colors. The most familiar natural material with structural color is the opal, where the dynamic iridescent colors come from periodically ordered arrays of monodispersed silica (SiO₂) spheres with diameters on the submicrometer scale. Structural coloration also plays an important role in the coloration in the animal organs, such as avian feathers, where the ordered arrays of melanosomes (submicrometer sized melanin-containing organelles in spherical, rod-like, or disk-like shapes with solid or hollow morphologies) contribute to dynamic colors. The wavelength of reflected structural color in these cases can be predicted using Bragg's equation (Equation 2):

$$λ = {( \frac{π}{3 \sqrt{2 ϕ}} )}^{1 / 3} {( \frac{8}{3} )}^{1 / 2} 2 {a ( {n}_{p}^{2} ϕ + {n}_{m}^{2} ( 1 - ϕ ) )}^{1 / 2} \qquad ( 2 )$$

where a is the radius of the particle, ϕ is the volume fraction of the particle, np is the particle refractive index and nm is the refractive index of the matrix, which varies depending on the internal (inter-granular) matrix composition.

### Example 2. Photonic Crystal Fabrication

Nanoparticles were synthesized from zein using a method adapted from Zhong et al. Zein was dissolved in a solvent and, through the addition of this solution to a non-solvent, the inherent hydrophobicity of zein led to the formation of zein colloidal particles via antisolvent precipitation. Briefly, zein dissolved into a solvent system of acetone, ethanol, ethylene glycol or methanol and water was sheared in a dropwise manner into a water bath. This led to the formation of dispersed droplets that due to the miscibility of the solvents in water led to the precipitation of the zein. The solvent, solvent to water ratio, and zein concentration were controlled, thus, the size of the nanoparticles was then controlled. 5% zein w/v was dissolved in an 80% v/v acetone/water solution. 1 mL of this solution was then dropped into 9 mL of water that was stirred at a rate of 800 rpm and at a drop rate of 1 mL/min through a 600 μm syringe needle. The resultant particles (e.g., size, surface charge, and polydispersity index) were characterized by dynamic light scattering (DLS, Malven Zetasizer nano-ZS90) measurements and scanning electron microscopy (SEM).

The zein nanoparticles were assembled into photonic crystals using drop casting or a more controlled vertical deposition method reported in literature. For drop casting, a ring of nanoparticles was deposited onto a substrate. For vertical deposition, this method was first prototyped using glass microscopic slides (1×2 cm²). Briefly, slides were washed sequentially in water, ethanol and acetone with sonication, and further cleaned in a UV-ozone chamber prior to use. The zein nanoparticles were suspended in deionized (DI) water and placed into a plastic cuvette, where the clean glass slide was held vertically in the solution at 60° C. to evaporate water. The nanoparticles self-assembled into photonic crystals comprised of highly ordered nano-structural arrays, due to the uniformity in size and surface charge properties of the particles. The thickness of photonic crystals was measured using profilometry and confirmed using a cross-sectional micrograph under SEM.

### Example 3. Modulation of Structural Colors

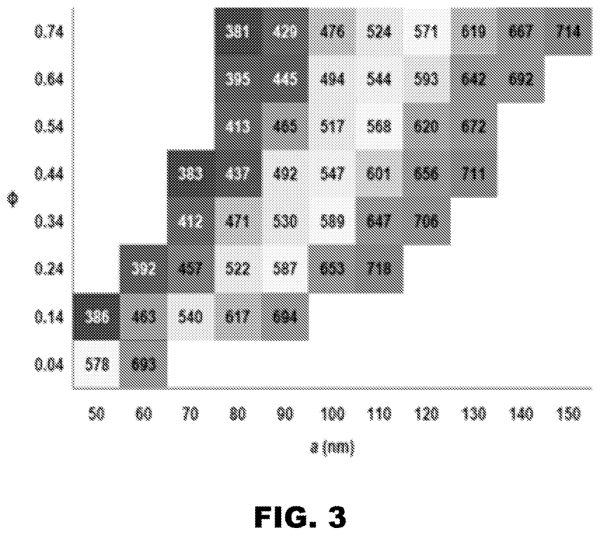

The synthesized photonic crystals produced structural colors observable by eye. The particle size and packing density of the photonic crystal films were modulated, and the natural light reflected and the scattering properties of the materials were controlled. The anticipated reflected wavelengths as functions of ϕ (volume fraction of the particle) versus a (radius of the particle) were estimated using Equation 2. Indeed, based on the calculations, a wavelength dependence on the nanoparticle radii, where only the wavelengths in the visible region will be reflected (FIG. 3) is anticipated. A refractive index of 1.49 of zein based nanoparticles has been reported by de Boer et al. This means that the size and spacing of the particles are the primary factors for controlling reflected wavelength, allowing more freedom in the morphology of manufactured particles. Further, the calculations support that the formulated nanoparticles generated a broad range of tunable visible colors, where the change in a and ϕ resulted in up to approximately 67% changes in wavelength. Based on this, the most effective particle morphology that had the greatest scattering efficiency (FIG. 3) could be chosen. Moreover, the calculations indicated that variations in visible color as a function of packing density of zein nanoparticles assembled as photonic crystals would be observed, which is an important feature in the design of a coloring system.

### Example 4. Structural Color Sensor Application

Pigment-based colorimetric sensors have been used in food packaging to enable in-situ and real-time monitoring of the quality and safety of packaged goods. However, these technologies have adapted poorly in the industry, as most synthetic pigments contain harmful substances, such as bromophenol, blue metalloporphyrins, phenol red, nile red, diphenylamine, malachite green, and cresol purple. Unlike existing pigment-based sensors, example embodiments of the sensors disclosed herein are prepared using zein nano-structures. Materials prepared using zein are safe for direct application in food contact surfaces and offer regulatory benefits for food contact application.

An example embodiment of the invention can be used as sensors in food systems for in-situ and rapid detection of food spoilages. Current techniques used to evaluate food spoilage analysis often require culture-based microbiology methods and/or liquid/gas chromatography analysis coupled with various detectors. These methods necessitate complicated and time-consuming sample extraction processes, in addition to the already high base price associated with capital, operation, and maintenance instrumentation. Furthermore, complicated, multiple step sample preparations are often required to improve the sensitivity of the analysis. Example embodiments of the invention have many advantages over traditional spoilage detection, such as real-time monitoring and non-destructive sampling, and can be done by non-expert consumers.

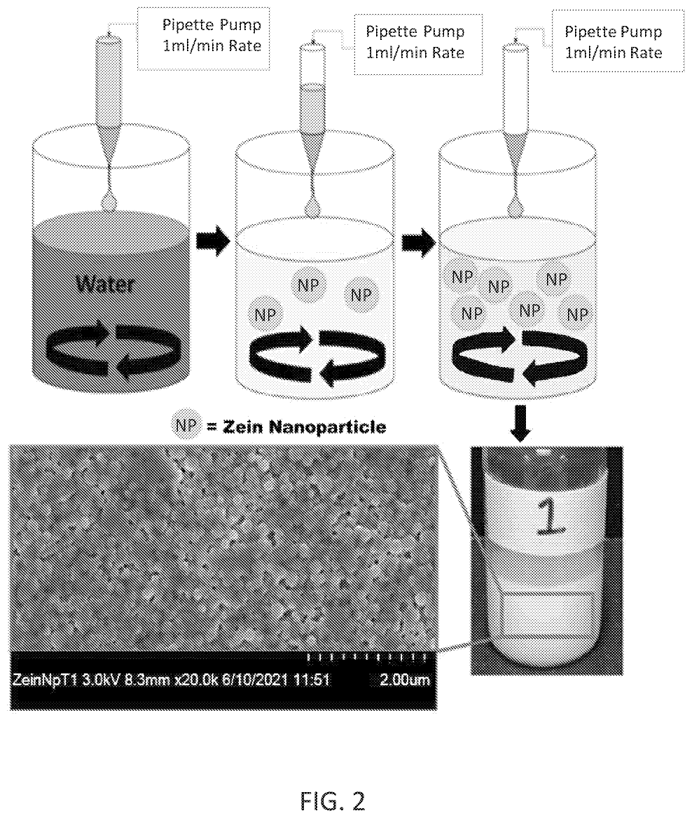

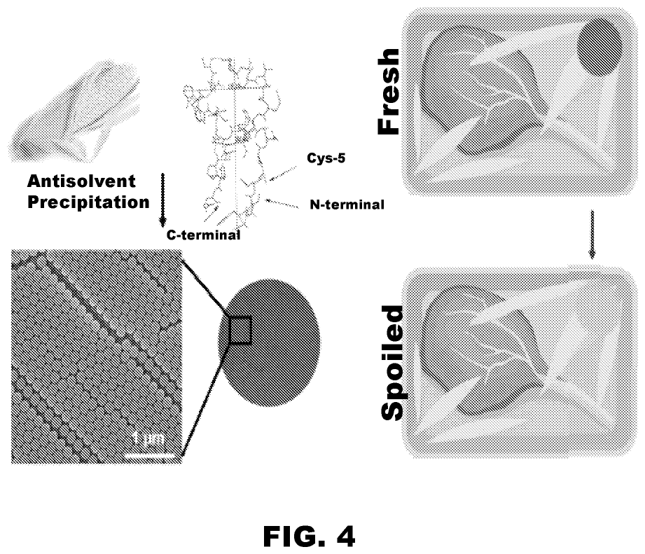

The photonic crystal color system comprised of assembled zein can be used as deployable optical sensors for food systems (concept illustrated in FIG. 4). The soluble zein is converted into nanoparticles with diameters that range from 50-300 nm via anti-solvent precipitation similar to previous protocols (FIG. 2). Then, the nanoparticles can be processed into thin film, photonic crystals that produce structural colors. The size of the particles, their packing density, and the thickness of the patterned films can be controlled, thus leveraging the natural light reflecting and scattering properties of these materials as smart optical sensors for detection of food spoilages. Organic vapors produced by food spoilages change the average refractive index of the photonic crystals and induce a global colorimetric change by adsorption into the nanoparticles. In this configuration, the sensors undergo a specific colorimetric response upon detection of target volatile organic compounds (VOC) that indicates oxidative or microbial spoilages in the headspace.

The use of photonic crystals is one of the most promising ways to solve the disadvantages with traditional and pigment-based colorimetric sensors because they can eliminate photobleaching and the use of toxic materials. Photonic crystals can generate structural colors that are less subject to light fading, are viewable in both bright sunlight and dimly lit environments, and less likely to migrate into food matrices. As electronic excitation is not involved in the coloration mechanism, the structural color is not susceptible to fading unless the nanostructure is destroyed. The nanostructure of photonic crystal sensors can be prepared using highly safe chemical substances. Materials prepared using zein can be directly used for food contact application and have potential regulatory benefits for food contact application.

### Example 5. Photonic Crystal Sensors for Detection of Volatile Organic Compounds (VOCs)

Colorimetric sensors used in various industries are often pigment-based, of which color properties are inherent of the material and depend on the chemical nature of the pigment. Some of the pigments, especially those containing organic dye molecules, can easily fade over time or upon exposure to light. More importantly, there is concern over unfavorable influences on health and the environment, as some pigments contain harmful substances. Spoilage indicating sensors have been reported in literature, but have limited commercial application in food packaging, because of the safety concerns and regulatory challenges due to toxicity of the materials. For example, Kuswandi et al (Kuswandi, B.; Maryska, C.; Jayus; Abdullah, A.; Heng, L. Y., Real time on-package freshness indicator for guavas packaging. Journal of Food Measurement and Characterization 2013, 7 (1), 29-39) reported a freshness indicator for guavas packaging using a toxic bromophenol blue dye as a colorimetric indicator. Lonsdale et al. (Lonsdale, C. L.; Taba, B.; Queralto, N.; Lukaszewski, R. A.; Martino, R. A.; Rhodes, P. A.; Lim, S. H., The use of colorimetric sensor arrays to discriminate between pathogenic bacteria. PLOS One 2013, 8 (5), e62726) developed colorimetric sensor arrays for bacterial detection using a variety of synthetic dyes, including metalloporphyrins, phenol red, nile red, and diphenylamine, as indicators. Salinas (Salinas, Y.; Ros-Lis, J. V.; Vivancos, J.-L.; Martinez-Máñez, R.; Marcos, M. D.; Aucejo, S.; Herranz, N.; Lorente, I.; Garcia, E., A novel colorimetric sensor array for monitoring fresh pork sausages spoilage. Food Control 2014, 35 (1), 166-176) reported a colorimetric array for monitoring pork spoilage using a series of synthetic dyes including toxic malachite green and cresol purple as indicators. For novel materials to be utilized in food packaging and food contact application, FDA requires proof of non-migratory or non-toxicity of the materials, which are challenging hurdles to overcome for pigment-based colorimetric sensors.

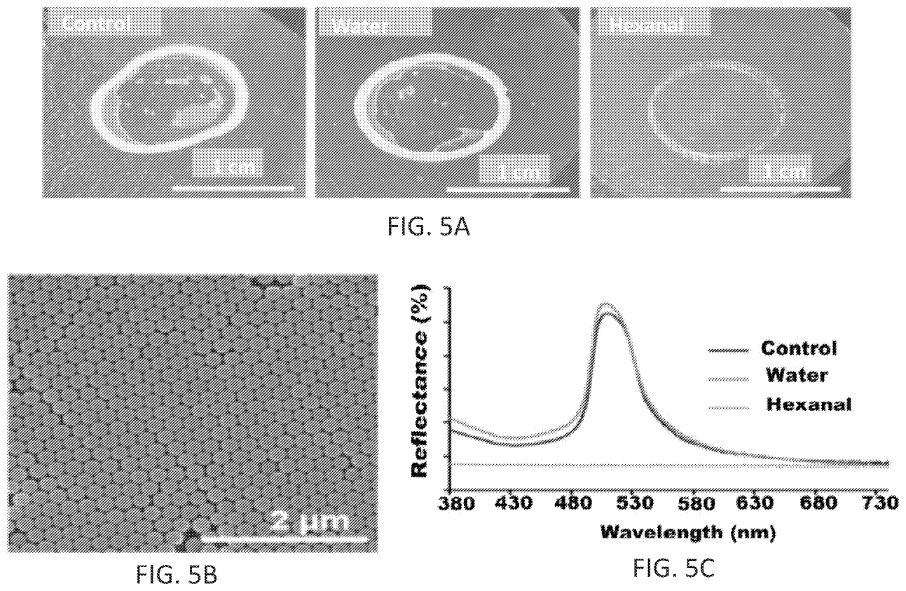

Volatile organic headspace sensing using photonic crystal sensors that were developed using polystyrene nanoparticles (FIG. 5) is demonstrated herein. Photonic crystals were fabricated by drop-casting 0.25 mL of 0.5% polystyrene nanoparticle (200 nm) suspension onto a clean glass slide, and drying the drop-casted suspension in air. Because of the size and relative surface charge of the particles, they naturally self-assembled into highly order nano-structural arrays (as suggested via SEM) and showed an iridescent green color under natural light (reflectance peak at 510 nm at an 8º tilt angle). In a proof-of-concept demonstration, when the photonic crystal sensors were taped underneath caps of 100 mL glass bottles that contained 20 mL of water or hexanal and sealed at room temperature overnight, the films turned clear and transparent only in the presence of the hexanal vapor, which is a VOC produced by lipid oxidation. The analysis suggested the photonic crystal exposed to hexanal had no reflectance peak in the visible light spectrum, while the sensor that was exposed to water vapor remained iridescent green in color, and had a reflectance peak at 510 nm. The results suggested the photonic crystal sensors had the potential to work for volatile organic compounds detection in headspace of food packages.

### Example 6. Edible Sensor Application

The zein nanoparticles can be assembled into a structural colored supraball and used as an edible sensor in food and consumer products (FIG. 6). The nanoparticles can be self-assembled into supraball structures via a reverse emulsion process. Briefly, zein nanoparticle aqueous suspension are mixed with an oil phase containing anhydrous-1-octanol. A water-in-oil emulsion is formed by vigorous vortexing. Supraballs are formed when the aqueous droplets are shrunk with water slowing migrating to the oil phase. The close packing of the nanoparticles within the supraballs enables formation of photonic crystals and produces colorful structural colors. A chitosan coating can be added to the supraballs to protect the structural integrity. Colorful supraballs are obtained when the oil phase is evaporated. The supraballs are applied as an edible colorimetric sensor in food and consumer products, where enzymes produced during food spoilage potentially hydrolyze the chitosan shell and destroy the nanostructure of the supraballs. The supraballs destroyed by food spoilage enzymes lose structural color and result in a color change in the product.

### Example 7. Zein-Based Adhesive for Green Packaging

Currently, the most-used adhesives are polymer-based glues that are composed of toxic and/or non-eco-friendly ingredients, such as toluene, hexane and cyanoacrylate. Protein-based natural adhesives have become a popular area of study due to the ease through which modifications can be added to proteins through the multitude of functional groups on proteins, as well as the ecofriendly nature of proteins. One issue with most proteins, however, is their poor resistance to water.

As a hydrophobic protein, zein has a high potential for the manufacturing of a protein-based adhesive that can be used in a water system, such as is needed for a paper-based coffee filter or tea bag.

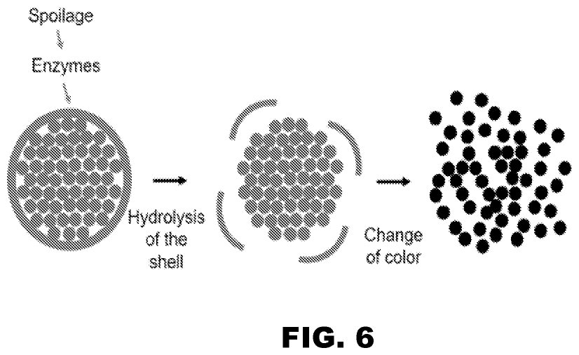

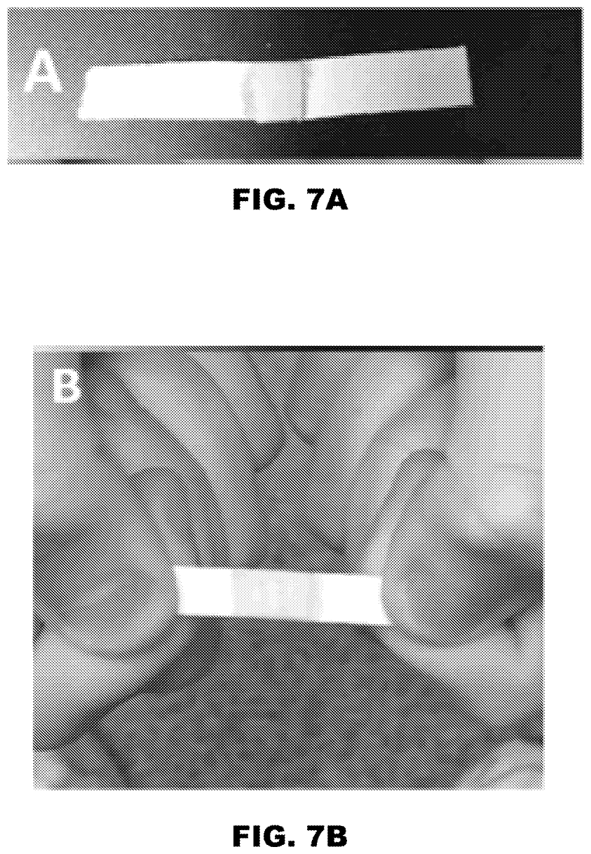

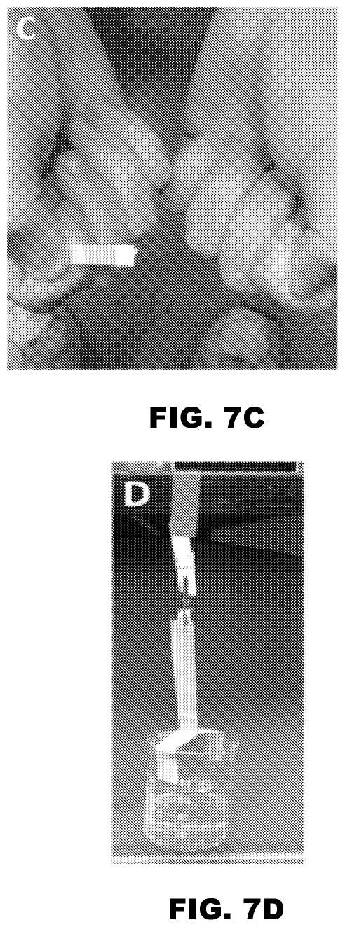

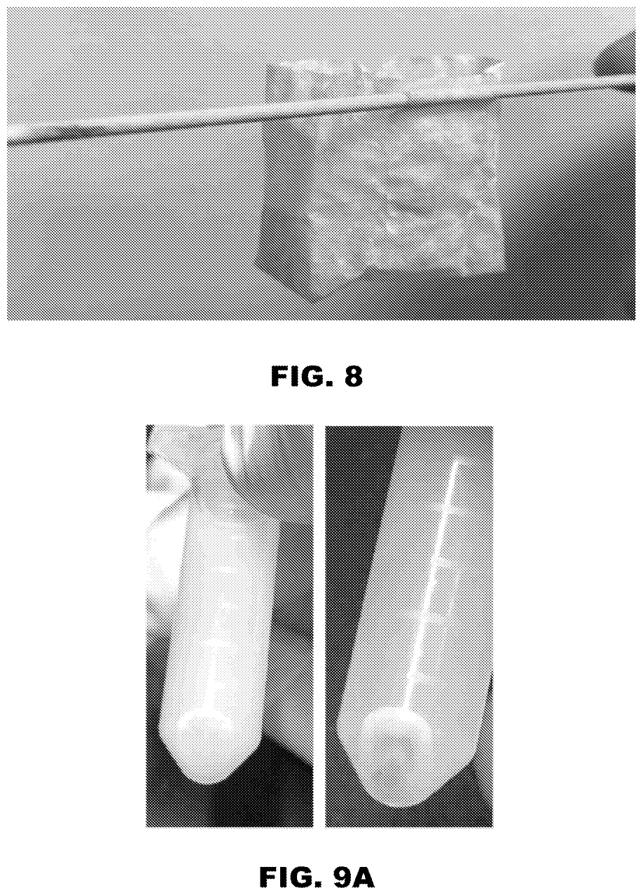

Zein adhesive was prepared by dissolving 50% w/v zein into a citric acid solution at a pH of 4.9. This citric acid solution was prepared by dissolving 7% citric acid into 80% w/w ethanol/water solution. This mixture was then allowed to cure for 48 hours in a sealed container. Once this was done, the material was utilized to bind together two pieces of cellulose paper. A preliminary tensile test highlighted the strength of the zein adhesive, as the paper failed before the adhesive did when under stress, as seen in FIGS. 7A-7D. In addition, the zein adhesive was used to generate paper-based containers that were able to retain water and their shape, as seen in FIG. 8.

### Example 8. Xanthommatin (Xa)-Incorporated Zein Nanoparticles for Next Generation of Edible Food Colorants

Food colorants are added to processed foods, drinks, and condiments to maintain and improve the appearance of the food and other consumer products. Both natural and artificial colorants are used in foods to add color, enhance color attributes, avoid color loss due to degradation, and provide consistency of coloring. Artificial food colorants are largely preferred by the food industry because they provide superior intensity and uniformity of color, are less expensive, more stable, and blend more easily with foods to produce an array of colors. At present, nine synthetic food dyes are approved by U.S. Food and Drug Administration (FDA). However, the use of artificial colorants has raised safety concerns and the evaluation of the chemical safety of artificial colorants has received particular scrutiny in many studies. For example, the possible allergenicity of food, drug, and cosmetic (FD&C) Yellow Number 5 (tartrazine) caused consumer concern in the 1980s, which had an impact on food labeling, and stimulated some processors to convert to natural colorants. The possible link between hyperactivity in children and the consumption of artificial food colorants has been studied, and it was concluded that the global hyperactivity aggregate score increased for some groups of children consuming a blend of synthetic food colorants compared with those consuming a placebo. It has been a focus of scientists and engineers in the food and cosmetic industry to replace certified artificial colorants with natural colorants in product formulations.

Natural colorants are chemically safer than artificial alternatives, and many may provide health benefits. However, naturally-derived colors are usually less vivid, and are usually less stable to heat, light, and oxygen. They may interact with other ingredients, resulting in the development of unwanted colors and flavors. In addition, naturally-derived color systems do not exist for all hues.

Xanthommatin (Xa) is a biopigment present in cephalopod chromatophores and arthropod skin. This unique biomolecule has the characteristics of a color change when it is oxidized and reduced, turning from yellow to red. This molecule has shown promise as an indicator and cytocompatible pigment. Here, a new application for Xa coupled with zein-based nanostructures created tunable photonic crystals rich in pigmentary color. The addition of a pigmentary component to photonic crystals reduced incoherent light scattering and mitigated angle dependent colors, which enabled colors to persist at multiple viewing angles. The interaction of Xa and zein is unique. However, zein nanoparticles have been shown to stabilize small molecules when they are able to encapsulate them during formation as seen with curcumin by Patel et al (Patel, A.; Hu, Y. C.; Tiwari, J. K.; Velikov, K. P., Synthesis and characterisation of zein-curcumin colloidal particles. Soft Matter 2010, 6 (24), 6192-6199).

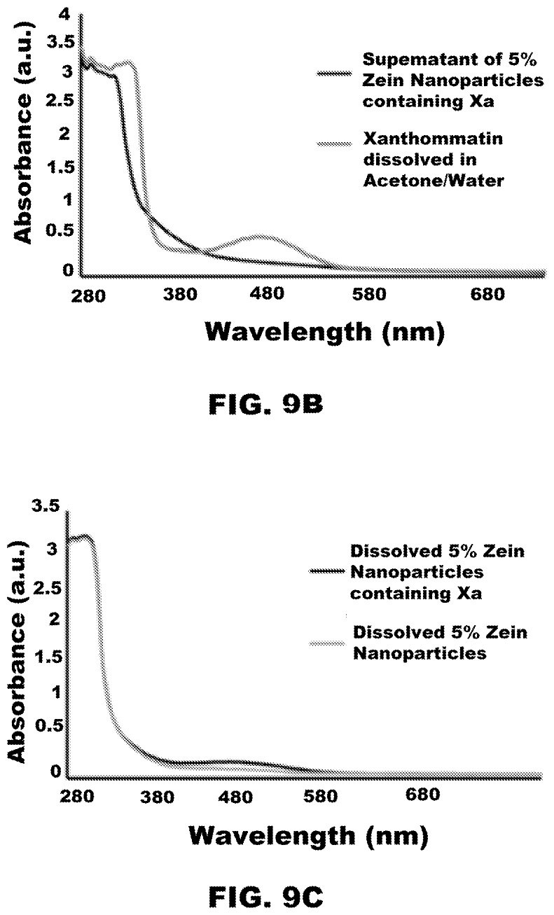

Preliminary results showed that Xa was encapsulated by zein through a variation of the protocol outlined by Zhong et al. 5% zein w/v was dissolved in an 80% v/v acetone/water solution that contained Xa. 1 mL of this solution was then dropped into 9 mL of water that was stirred at a rate of 800 rpm at a drop rate of 1 mL/min through a 600 μm syringe needle. The resultant particles (size, surface charge, and polydispersity index) were characterized by dynamic light scattering (DLS, Malven Zetasizer nano-ZS90) measurements and scanning electron microscopy (SEM). By visual observation, the pellet of nanoparticles after centrifugation at 5,000 rcf for 5 minutes yielded a colored pellet as compared to pure nanoparticles, which indicated the presence of Xa. A photograph of the resulting mixture is reproduced as FIG. 9A. Analysis of the supernatant of the Xa-zein nanoparticles mixture revealed that there was no xanthommatin present in the mixture, which supported the conclusion that the Xa was encapsulated by the zein when the nanoparticles were formed (FIG. 9B). Xa encapsulation in the nanoparticles was observed through the dissolution of the zein nanoparticles in 80% acetone/water after washing. As seen in FIG. 9C, the zein nanoparticles that were formed with Xa had an absorbance peak at about 450 nm, which corresponds to a characteristic Xa peak, and showed that incorporation of Xa into the nanoparticles had occurred.

### Example 9. Fabrication of Zein Nanoparticle Solutions

Zein nanoparticles were fabricated using the following process:
1. Measured out 1.5 g of zein;
2. Made and mixed a 65% solution of ethanol in water (13 mL ethanol 7 mL water);
3. Poured ethanol solution into zein and vortexed to mix well (making 7.5% zein solution);
4. Set a stir plate to 800 rpm and put a vial with 9 mL of water and a stir bar on it;
5. Set up syringe pump to correct diameter of the syringe and set flow rate to 2 mL/min;
6. Added zein solution to syringe with needle (added more volume than needed);
7. Dropped 1 mL of zein into the vial spinning with water;
8. Took 100 μL of zein nanoparticle solution and pipetted it into 900 μL water in a cuvette.

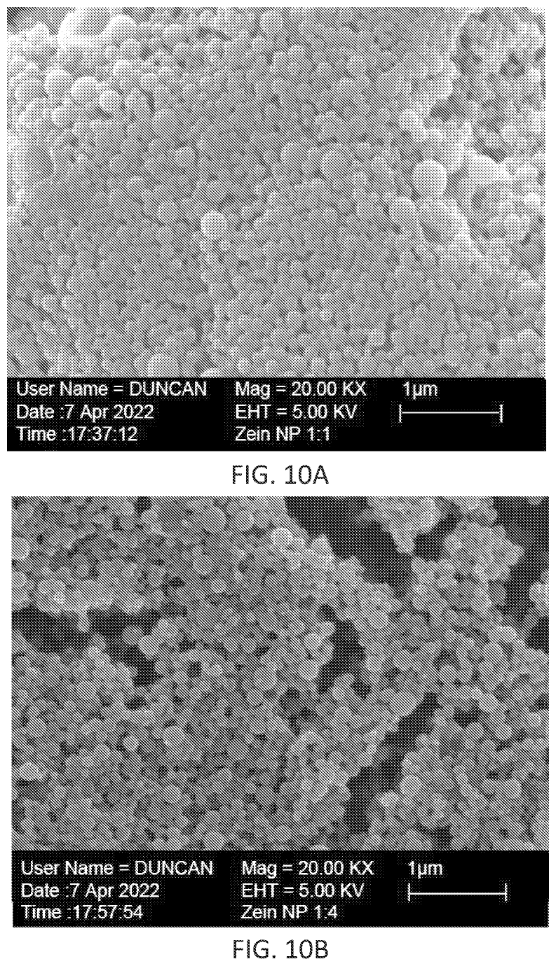

Ten batches of zein nanoparticles of 10 mL each were made according to the foregoing procedure, and then combined to make 100 mL of zein nanoparticles having diameters of approximately 150 nm. Aliquots of the resulting yellow suspension were diluted and analyzed using SEM to obtain the SEM images depicted in FIGS. 10A and 10B. Different aliquots of the resulting yellow suspension were drop-casted into iridescent blue films (FIG. 11A) and analyzed for optical performance (FIG. 11B).

### Example 10. Nanoparticle Protocol

### Materials:

Zein powder
70% ethanol
10 mL syringe
Needle
Mechanical pump
Stir plate
Stir bar
Scintillation vial
1000 μL pipette and tips
10 mL capped vial
100 μL pipette and tips
Centrifuge tubes
Disposable cuvette

### Nanoparticle Dropping

1. Made 7.5% w/v zein solution using 70% ethanol.
2 Measured the diameter of a 10 ml syringe.
3. Input the diameter of the syringe into the mechanical pump in millimeters under “Diameter” and set “Rate” to 120 mL/hour.
4. Put a needle on the syringe and added 10 mL of 7.5% zein solution into the syringe.
5. Placed the syringe on the mechanical pump and secured it using the twist out holder.
   a) Placed the pusher of the mechanical pump against the top of the plunger on the syringe.
   b) Using the “Volume” setting, tested the attachment of the syringe by starting the mechanical pump until zein comes out of the syringe.
   c) When cleaning the needle after dropping, used a dry paper towel or a paper towel damp with 70% ethanol.
6. Set the stir plate to 800 rpm and added tape/markings to the stir plate to mark the center in order to keep vial placement consistent.
7 Pipetted 9 mL of anti-solvent into the scintillation vial using a 1000 μL pipette.
8. Added a stir bar into the vial and placed the vial at the center of the stir plate. Note: there should be a small vortex formed around the center of the vial.
9. Placed the mechanical pump over the center of the vial and dropped 1 mL of zein solution.
10. Removed immediately after dropping and decanted into a 10 mL capped vial. Note: there may be aggregation formed: do not pour into capped vials.

### DLS Analysis

1. In a cuvette, pipetted 100 μL of nanoparticles and pipetted 900 μL of DI water.
2. Placed the cuvette in the Zetasizer DLS instrument.
3. Under “Size”, changed material to “Protein” and dispersant to the appropriate dilution of anti-solvent.

### Ultra-Purification of Nanoparticles

1. Placed 1 mL of nanoparticles in the centrifuge tube.
2. Centrifuged at 10,000 rfc for 15 minutes.
3. Using a pipette, separated the supernatant into a new centrifuge tube.
4. Added 500 μL of DI water into the original centrifuge tube to resuspend the top level of the pellet.
5. Using a pipette, separated the resuspended top layer of the pellet into a new centrifuge tube. Note: this is the most isolated nanoparticles location.

In a series of optimization experiments wherein the anti-solvent was water, various salts were added to the anti-solvent during nanoparticle dropping, and the effect of the salt on average diameter, average polydispersity index (PDI) and average zeta potential was measured. Table 1 summarizes the average diameter, average PDI and average zeta potential of nanoparticles dropped into water containing no salt, NaCl, CaCl₂ or CaCl₂.

TABLE 1
Overview of Optimization Data For Zein Nanoparticles

| | Avg Diameter ± Standard | Avg | Avg Zeta Potential |
|---|---|---|---|
| [Salt] | Deviation (nm) | PDI | (mV) |
| No salt | 160.5 ± 3.42 | 0.146 | 36.7 |
| 7 mM NaCl | 183.0 ± 3.83 | 0.160 | 24.5 |
| 7 mM CaCl₂ | 190.5 ± 8.14 | 0.160 | 31.6 |
| Ultra-purified | 147.9 ± 2.46 | 0.088 | 47.2 |
| 3.5 mM | | | |
| CaCl₂ | | | |

The data in Table 1 shows that the presence of salt (e.g., 7 mM salt) increases the average sizes of the nanoparticles, possibly contributing to the change in visible color. The ultra-purified nanoparticles (3.5 mM CaCl₂)) had the most uniformity, as indicated by the smallest PDI and the least potential to aggregate in solution, as indicated by the highest zeta potential

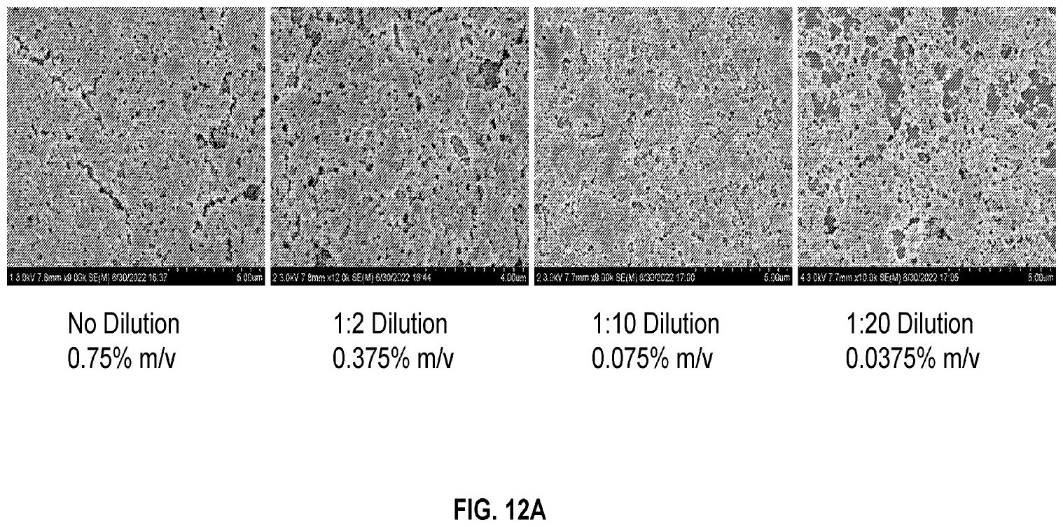

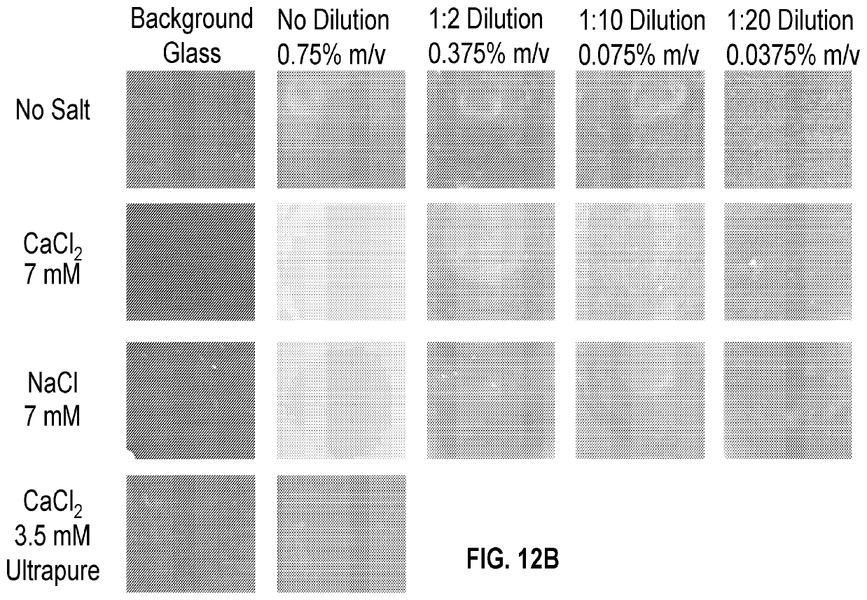

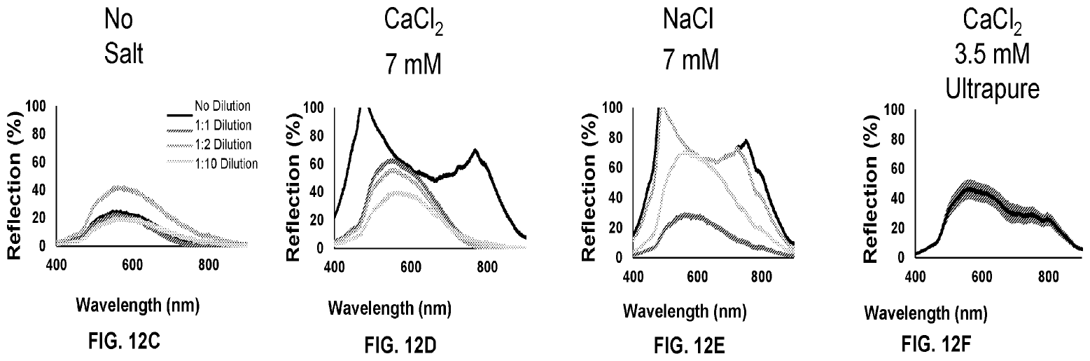

Zein nanoparticles synthesized using the 7 mM NaCl conditions were dropped onto glass and analyzed by SEM. FIG. 12A shows the SEM images of various dilutions of the nanoparticles dropped onto glass using a 10 μl drop size.

Zein nanoparticles synthesized under each of the optimization conditions described in Table 1 were diluted or not diluted and casted into films dropped onto glass. FIG. 12B shows the bright field images of the zein nanoparticle films dropped onto glass, and FIGS. 12C-12F show reflectance data for the films created for all conditions with various dilution factors. Reflectance data for the ultrapure nanoparticle film is an average of four measurements (no dilutions) with corresponding standard deviations.

The influence of salt during fabrication and casting stages impacts the resultant visible colors reflected from the zein films. These colors are also controlled by the dilution factor/volume fraction of the casted films.

### REFERENCES

1. Patel, A. R.; Velikov, K. P., Zein as a source of functional colloidal nano- and microstructures. Current Opinion in Colloid & Interface Science 2014, 19 (5), 450-458.
2. Wei, Y. X.; Yao, J. R.; Shao, Z. Z.; Chen, X., Water-Resistant Zein-Based Adhesives. Acs Sustainable Chemistry & Engineering 2020, 8 (20), 7668-7679
3. Zhong, Q. X.; Jin, M. F., Zein nanoparticles produced by liquid-liquid dispersion. Food Hydrocolloids 2009, 23 (8), 2380-2387.
4. Wrolstad, R. E.; Culver, C. A., Alternatives to those artificial FD&C food colorants. Annu Rev Food Sci Technol 2012, 3, 59-77.
5. S; K.; MF., J. Food Dyes, A Rainbow of Risks; Center for Science in the Public Interest, 2010.
6. FDA Color Additive Inventories. https://www.fda.gov/industry/color-additives/color-additive-inventories (accessed 03/23).
7. Marmion, D. M., Handbook of US colorants: foods, drugs, cosmetics, and medical devices. John Wiley & Sons: 1991.
8. Authority, E. F. S., Assessment of the results of the study by McCann et al. (2007) on the effect of some colours and sodium benzoate on children's behaviour-Scientific Opinion of the Panel on Food Additives, Flavourings, Processing Aids and Food Contact Materials (AFC). EFSA Journal 2008, 6 (3), 660.
9. Committee, F. A. Certified Color Additives in Food and Possible Association with Attention Deficit Hyperactivity Disorder in Children; FDA/CFSAN, 2011.
10. McCann, D.; Barrett, A.; Cooper, A.; Crumpler, D.; Dalen, L.; Grimshaw, K.; Kitchin, E.; Lok, K.; Porteous, L.; Prince, E., Food additives and hyperactive behaviour in 3-year-old and 8/9-year-old children in the community: a randomised, double-blinded, placebo-controlled trial. The lancet 2007, 370 (9598), 1560-1567.
11. Tadepalli, S.; Slocik, J. M.; Gupta, M. K.; Naik, R. R.; Singamaneni, S., Bio-Optics and Bio-Inspired Optical Materials. Chem. Rev. 2017, 117 (20), 12705-12763.
12. Kinoshita, S.; Yoshioka, S.; Miyazaki, J., Physics of structural colors. Rep. Prog. Phys. 2008, 71 (7), 076401.
13. Marlow, F.; Sharifi, P.; Brinkmann, R.; Mendive, C., Opals: status and prospects. Angewandte Chemie International Edition 2009, 48 (34), 6212-6233.
14. Zi, J.; Yu, X.; Li, Y.; Hu, X.; Xu, C.; Wang, X.; Liu, X.; Fu, R., Coloration strategies in peacock feathers. Proceedings of the National Academy of Sciences 2003, 100 (22), 12576-12578.
15. Rundquist, P. A.; Photinos, P.; Jagannathan, S.; Asher, S. A., Dynamical Bragg diffraction from crystalline colloidal arrays. The Journal of chemical physics 1989, 91 (8), 4932-4941.
16. Xiao, M.; Li, Y.; Allen, M. C.; Deheyn, D. D.; Yue, X.; Zhao, J.; Gianneschi, N. C.; Shawkey, M. D.; Dhinojwala, A., Bio-inspired structural colors produced via self-assembly of synthetic melanin nanoparticles. ACS nano 2015, 9 (5), 5454-5460.
17. Yang, X.; Ge, D.; Wu, G.; Liao, Z.; Yang, S., Production of Structural Colors with High Contrast and Wide Viewing Angles from Assemblies of Polypyrrole Black Coated Polystyrene Nanoparticles. ACS Appl Mater Interfaces 2016, 8 (25), 16289-95.
18. de Boer, F. Y.; Kok, R. N. U.; Imhof, A.; Velikov, K. P., White zein colloidal particles: synthesis and characterization of their optical properties on the single particle level and in concentrated suspensions. Soft Matter 2018, 14 (15), 2870-2878.
19. Xiao-wei, H.; Xiao-bo, Z.; Ji-yong, S.; Zhi-hua, L.; Jie-wen, Z., Colorimetric sensor arrays based on chemo-responsive dyes for food odor visualization. Trends in Food Science & Technology 2018, 81, 90-107.
20. Kuswandi, B.; Maryska, C.; Jayus; Abdullah, A.; Heng, L. Y., Real time on-package freshness indicator for guavas packaging. Journal of Food Measurement and Characterization 2013, 7 (1), 29-39.
21. Lonsdale, C. L.; Taba, B.; Queralto, N.; Lukaszewski, R. A.; Martino, R. A.; Rhodes, P. A.; Lim, S. H., The use of colorimetric sensor arrays to discriminate between pathogenic bacteria. PLOS One 2013, 8 (5), e62726.
22. Salinas, Y.; Ros-Lis, J. V.; Vivancos, J.-L.; Martinez-Máñez, R.; Marcos, M. D.; Aucejo, S.; Herranz, N.; Lorente, I.; Garcia, E., A novel colorimetric sensor array for monitoring fresh pork sausages spoilage. Food Control 2014, 35 (1), 166-176.
23. Anonymous Packaging & Food Contact Substances (FCS). https://www.fda.gov/food/food-ingredients-packaging/packaging-food-contact-substances-fcs (accessed Feb. 25, 2020).
24. Katagiri, K.; Tanaka, Y.; Uemura, K.; Inumaru, K.; Seki, T.; Takeoka, Y., Structural color coating films composed of an amorphous array of colloidal particles via electrophoretic deposition. NPG Asia Materials 2017, 9 (3), e355-e355.
25. McClements, D. J.; Decker, E. A., Lipid Oxidation in Oil-in-Water Emulsions: Impact of Molecular Environment on Chemical Reactions in Heterogeneous Food Systems. Journal of food science 2000, 65 (8), 1270-1282.
26. Jiang, Q. R.; Reddy, N.; Yang, Y. Q., Cytocompatible cross-linking of electrospun zein fibers for the development of water-stable tissue engineering scaffolds. Acta Biomaterialia 2010, 6 (10), 4042-4051.
27. Patel, A.; Hu, Y. C.; Tiwari, J. K.; Velikov, K. P., Synthesis and characterisation of zein-curcumin colloidal particles. Soft Matter 2010, 6 (24), 6192-6199.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

1. A photonic crystal comprising a plurality of substantially uniform zein particles.

2. The photonic crystal of claim 1, in the form of a film.

3. The photonic crystal of claim 2, in the form of a thin film.

4. The photonic crystal of claim 1, in the form of a coating.

5. The photonic crystal of claim 1, wherein the plurality of substantially uniform zein particles have a polydispersity index of about 0.2 or less.

6. The photonic crystal of claim 1, wherein the plurality of substantially uniform zein particles have a mean diameter of about 50 nanometers to about 300 nanometers.

7. The photonic crystal of claim 6, wherein the plurality of substantially uniform zein particles have a mean diameter of about 145 nanometers to about 200 nanometers.

8. The photonic crystal of claim 1, wherein the plurality of substantially uniform zein particles have a volume fraction (q) of about 0.04 to about 0.95.

9. The photonic crystal of claim 1, wherein the plurality of substantially uniform zein particles have a volume fraction (q) of about 0.70 to about 0.95.

10. The photonic crystal of claim 1, wherein the plurality of substantially uniform zein particles have a mean zeta potential of about 20 to about 60 mV.

11. The photonic crystal of claim 1, wherein the plurality of substantially uniform zein particles have a particle packing density that is about 1% of the photonic crystal volume to about 100% of the photonic crystal volume.

12. The photonic crystal of claim 1, wherein the plurality of substantially uniform zein particles have a particle packing density that is about 90% of the photonic crystal volume.

13. The photonic crystal of claim 1, wherein the photonic crystal imparts a blue color.

14. The photonic crystal of claim 1, wherein the zein particles comprise a pigment.

15. The photonic crystal of claim 14, wherein the pigment is xanthommatin.

16. The photonic crystal of claim 14, wherein the pigment is encapsulated in the zein particles.

17. A colorant comprising a photonic crystal of claim 1.

18. A composition comprising a photonic crystal of claim 1, wherein the composition is formulated for oral use.

19. A composition comprising a photonic crystal of claim 1, wherein the composition is formulated for topical use.

20. The composition of claim 18, for use as a consumer product.

21. The composition of claim 20, for use as a food, drug or cosmetic.

22. A method of fabricating the photonic crystal of claim 1, comprising assembling a plurality of substantially uniform zein particles into one or more ordered and periodic structures that generate structural color, thereby fabricating the photonic crystal.

23. A method of fabricating the photonic crystal of claim 1, comprising:
a) providing a mixture comprising a plurality of substantially uniform zein particles in a liquid;
b) applying the mixture to a surface; and
c) evaporating the liquid, thereby assembling the plurality of substantially uniform zein particles into one or more ordered and periodic structures that generate structural color,
thereby fabricating a photonic crystal.

24. A method of imparting a color to a surface, comprising coating a surface, or a portion thereof, with a photonic crystal of claim 1.

25. A method of imparting a color to a surface, comprising:
a) providing a mixture comprising a plurality of substantially uniform zein particles in a liquid; and
b) applying the mixture to a surface, and
c) evaporating the liquid to produce one or more photonic crystals comprising the substantially uniform zein particles,
thereby imparting a color to the surface.

26. The mixture of claim 23, wherein the liquid comprises water.
